(19) United States
(12) Patent Application Publication
(10) Pub. No.: US 2016/0035765 A1
(43) Pub. Date: Feb. 4, 2016

(54) METHOD OF FABRICATING METAL WIRING AND THIN FILM TRANSISTOR SUBSTRATE

(71) Applicant: Samsung Display Co., Ltd., Yongin-city (KR)

(72) Inventors: Seung-Ho YOON, Yongin-City (KR); Su-Bin BAE, Yongin-City (KR); Yu-Gwang JEONG, Yongin-City (KR)

(21) Appl. No.: 14/706,858

(22) Filed: May 7, 2015

(30) Foreign Application Priority Data
Jul. 29, 2014 (KR) 10-2014-0096523

(51) Int. Cl. H01L 27/12

(52) U.S. Cl. CPC H01L 27/1288; H01L 27/1262

(57) ABSTRACT

A method of fabricating metal wiring, including: sequentially forming first and second conductive layers on a substrate; forming a first photosensitive film pattern on the first and second conductive layers; forming first and second conductive patterns by etching parts of the first and second conductive layers by using the first photosensitive film pattern as a mask; forming a second photosensitive film pattern positioned inside the first photosensitive film pattern by a predetermined interval by ashing the first photosensitive film pattern; etching an exposed first conductive pattern by using the second photosensitive film pattern as a mask; and removing the second photosensitive film pattern.

### CROSS-REFERENCE TO RELATED APPLICATION

This application claims priority from and the benefit of Korean Patent Application No. 10-2014-0096523, filed on Jul. 29, 2014, which is hereby incorporated by reference for all purposes as if fully set forth herein.

### BACKGROUND

1. Field

Exemplary embodiments relate to a method of fabricating metal wiring, and a method of fabricating a thin film transistor substrate.

2. Discussion of the Background A thin film transistor substrate is used as a substrate of a liquid crystal display device or an organic light emitting display device including pixels in a matrix array.

The liquid crystal display device or the organic light emitting display device may be constructed to have larger sizes and higher resolutions, so that increasingly higher signal processing speeds are required. As a result, a low resistance metal material is needed for use as a wiring material to allow the higher signal processing speeds without undesirable signal degradation.

Accordingly, the low resistance metal material may be replaced with copper (Cu) having a non-resistance characteristic and an electron movement characteristic which are more desirable than that of the existing metal wiring material.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a method of fabricating metal wiring and a method of fabricating a thin film transistor substrate that are capable of improving reliability by removing titanium (Ti) residues remaining on a lateral surface of copper (Cu).

Additional aspects will be set forth in the detailed description which follows, and, in part, will be apparent from the disclosure, or may be learned by practice of the inventive concept.

An exemplary embodiment of the present invention provides a method of fabricating metal wiring, including: sequentially forming first and second conductive layers on a substrate; forming a first photosensitive film pattern on the first and second conductive layers; etching parts of the first and second conductive layers by using the first photosensitive film pattern as a mask to form first and second conductive patterns; forming a second photosensitive film pattern inside the first photosensitive film pattern by a predetermined interval by ashing the first photosensitive film pattern; etching an exposed first conductive pattern by using the second photosensitive film pattern as a mask; and removing the second photosensitive film pattern. Another exemplary embodiment of the present invention provides a method of fabricating a thin film transistor substrate, including: forming gate wiring extended in a first direction and a gate electrode connected to the gate wiring in a switching region on a substrate having a pixel region and the switching region arranged within the pixel region; forming a gate insulating layer on the gate wiring and a gate electrode; forming a semiconductor layer overlapping the gate electrode, data wiring extended in a second direction crossing the gate wiring, a source electrode connected to the data wiring, and a drain electrode spaced apart from the source electrode by a predetermined interval on the gate insulating layer; forming a passivation layer including a contact hole for exposing a part of the drain electrode on the data wiring, the source electrode, and the drain electrode; and forming a pixel electrode, which is in contact with the drain electrode through the contact hole, on the passivation layer. The forming of the gate wiring and the gate electrode includes: sequentially forming first and second conductive layers on the substrate; forming a first photosensitive film pattern on the first and second conductive layers; forming first and second conductive patterns by etching parts of the first and second conductive layers by using the first photosensitive film pattern as a mask; forming a second photosensitive film pattern inside the first photosensitive film pattern by a predetermined interval by ashing the first photosensitive film pattern; etching an exposed first conductive pattern by using the second photosensitive film pattern as a mask; and removing the second photosensitive film pattern.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1A, FIG. 1B, FIG. 1C, FIG. 1D, FIG. 1E, FIG. 1F, and FIG. 1G are cross-sectional views sequentially illustrating a process of fabricating metal wiring according to an exemplary embodiment of the present invention.

FIG. 2 is a top plan view of a liquid crystal display device, to which the metal wiring according to the exemplary embodiment of the present invention is applied.

FIG. 3 is a cross-sectional view taken along line I-I′ of FIG. 2.

FIG. 4A, FIG. 4B, FIG. 4C, FIG. 4D, FIG. 4E, FIG. 4F, FIG. 4G, FIG. 4H, FIG. 4I, FIG. 4J, FIG. 4K, and FIG. 4L are cross-sectional views sequentially illustrating a process of fabricating the liquid crystal display device of FIG. 3.

FIG. 5 is an SEM picture for the process of fabricating the metal wiring according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. It will be understood that when an element is referred to as being “between” two elements, it can be the only element between the two elements, or one or more intervening elements may also be present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

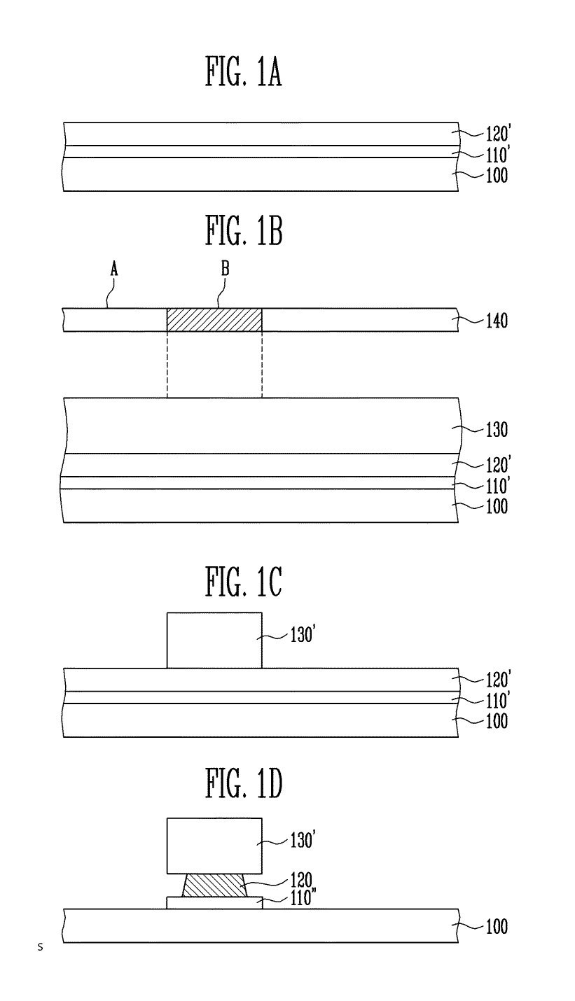

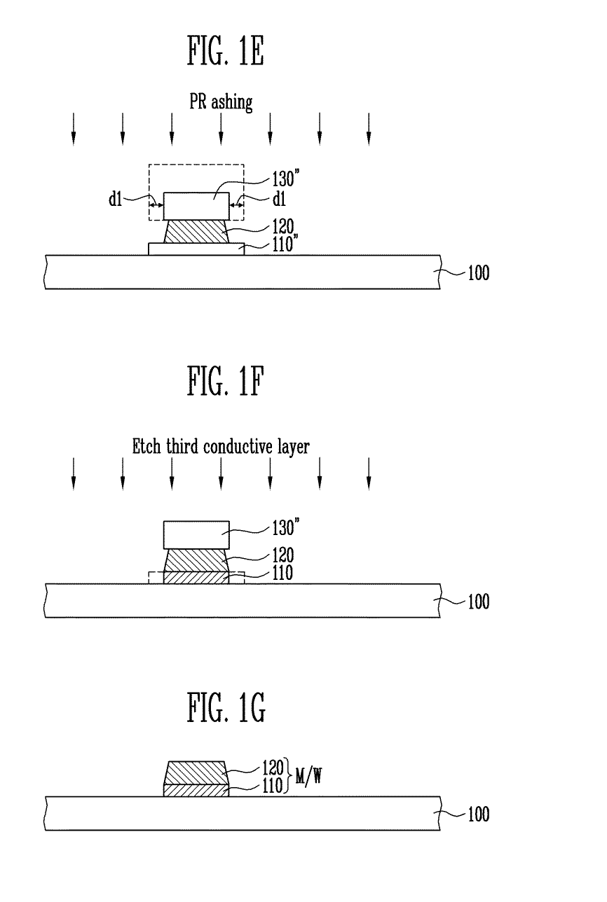

Referring to FIG. 1A, a first conductive layer 110′ and a second conductive layer 120′ are sequentially formed on a substrate 100, which may be a transparent substrate, such as glass, a flexible substrate, such as quartz, ceramic, silicon, and plastic.

The second conductive layer 120′ is formed of a copper conductive layer, including copper (Cu) or a copper alloy, has resistivity of 2.1 μΩcm, which is low, in a thin film state, has relatively low cost, so that the second conductive layer 120′ may be used as low resistance wiring. The second conductive layer 120′ formed of the copper (Cu) conductive layer may have a thickness of 2,000 to 8,000 Å.

The first conductive layer 110′ increases adhesion between the substrate 100 and the second conductive layer 120′, and serves as a barrier for preventing copper ions of the second conductive layer 120′ from being diffused to the substrate 100. The first conductive layer 110′ may be used as a material having excellent chemical-resistant characteristics and having large etching selectivity with the second conductive layer 120′ that is the copper (Cu) conductive layer. For example, the first conductive layer 110′ may include chromium (Cr), titanium (Ti), tantalum (Ta), manganese (V), zirconium (Zr), tungsten (W), niobium (Nb), cobalt (Co), nickel (Ni), lead (Pd), platinum (Pt), or a compound thereof. For example, titanium (Ti) may be used in an exemplary embodiment.

The first conductive layer 110′ formed of the titanium (Ti) conductive layer may have a thickness of 0 to 500 Å.

Referring to FIG. 1B, a photoresist film 130 is formed on the substrate 100 on which the first and second conductive layers 110′ and 120′ are sequentially formed. An exposure mask 140 spaced apart from the photoresist layer 130 by a predetermined interval is disposed on the photoresist film 130, and then a first photoresist pattern 130′ illustrated in FIG. 1C is formed through a mask process including a series of unit processes, such as exposure, development, and etching. The exposure mask 140 includes a transmissive unit A for allowing light to pass through, and a blocking unit B for blocking light.

Referring to FIG. 1D, a second conductive pattern 120 and a third conductive layer 110″ are formed by performing a wet etching process on the first and second conductive layers 110′ and 120′ formed on the substrate 100 by using the first photoresist pattern 130′ as an etching mask. The first and second conductive layers 110′ and 120′ formed on the substrate 100 are etched in the wet etching process in a batch manner.

In this case, oxon (2KHSO₅.KHSO₄.K₂SO₄) for etching the copper (Cu) conductive layer, and a mixed liquid in which oxon and ammonium fluoride (NH₄F) are mixed for etching the titanium (Ti) conductive layer may be used as an etchant used in the wet etching process.

Referring to FIG. 1E, a second photoresist pattern 130″ is formed so that both lateral surfaces of the third conductive layer 110″ are exposed to the outside by ashing processing the first photoresist pattern 130′. A spaced distance dl between the first and second photoresist patterns 130′ and 130″ may be 0 to 0.4 μm, for example, 0.2 to 0.3 μm.

Referring to FIG. 1F, a first conductive pattern 110 having a pattern structure corresponding to the second photoresist pattern 130″ is formed by etching processing the third conductive layer 110″ exposed to the outside by using the second photoresist pattern 130″ as an etching mask.

In the etching operation, a dry etching method is used, reaction gas including any one of SF₆ and CF₄ with helium (He) as a base, may be selected. Particularly, the helium (He) may have a flow rate about 50 to 150 sccm (standard cubic centimeter per minute, a unit of a flow rate representing that a quantity of 1 cc flows per minute) within a vacuum chamber, and SF₆ may also have a flow rate about 50 to 150 sccm.

The pressure within the vacuum chamber may be set to be 10 to 50 mtorr, a source of the RF power may be set to have 500 to 2,000 W, and a bias power level may be set at 0 to 1,000 W.

It is known to use an O₂ or Cl gas base in the dry etching process, and in this case, the copper (Cu) conductive layer reacts with the O₂ or Cl gas, so that the copper (Cu) conductive layer may become corroded. Accordingly, it is possible to prevent the copper (Cu) conductive layer from being corroded by using helium (He) gas in the dry etching process.

Referring to FIG. 1G, the first and second conductive patterns 110 and 120 sequentially formed on the substrate 100 are formed by removing the second photoresist pattern 130″. The first and second conductive patterns 110 and 120 finally configure metal wiring (M/W) having a dual conductive layer structure.

In the meantime, a capping layer for protecting the second conductive pattern 120 may be formed on the metal wiring M/W. The capping layer may be formed of a material which may be etched by the same etchant as that of the second conductive pattern 120 in a batch manner. For example, a copper (Cu) conductive layer may be used for the capping layer.

The metal wiring M/W formed as described above removes the titanium (Ti) conductive layer remaining on the lateral surface of the second conductive pattern 120 through the ashing process of the second photoresist pattern 130″ and the dry etching using the helium (He) gas as the base, thereby preventing the lateral surface of the second conductive pattern 120 from being over etched. Thus, corrosion is inhibited or prevented, thereby improving reliability.

The aforementioned method of fabricating the metal wiring M/W is applicable to a thin film transistor substrate used in a liquid crystal display device, an organic light emitting display device, a semiconductor element, a semiconductor device, and the like, and in addition, is applicable to any field demanding a precise wiring pattern. Hereinafter, an example in which the method of fabricating the metal wiring M/W according to the exemplary embodiment of the present invention is applied to a thin film transistor substrate will be described, but the present invention is not limited thereto.

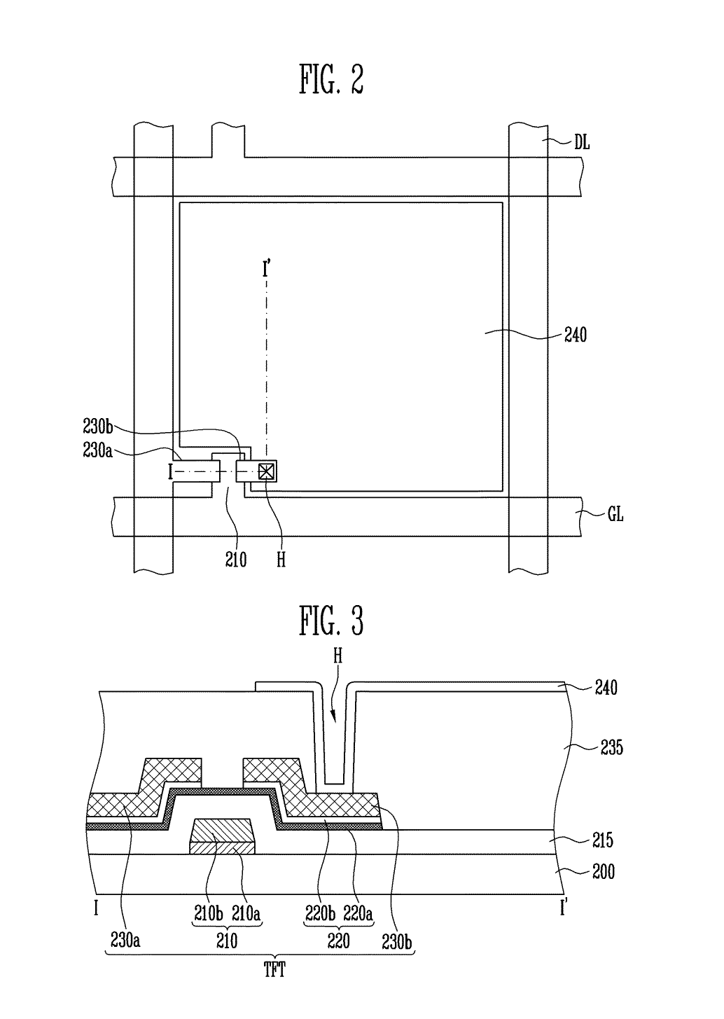

FIG. 2 is a top plan view of a liquid crystal display device to which the metal wiring is applied, and FIG. 3 is a cross-sectional view taken along line I-I′ of FIG. 2.

Referring to FIGS. 2 and 3, gate wiring GL is formed on a substrate 200 in a predetermined direction, and data wiring DL defining a pixel region while crossing the gate wiring GL is formed. Further, a thin film transistor TFT is formed at a crossing point of the two wirings GL and DL, and a pixel electrode 240 connected with the thin film transistor TFT is formed in a pixel region.

The thin film transistor TFT includes a gate electrode 210 having a form branched from the gate wiring GL, a source electrode 230a, and a drain electrode 230b, which are branched from the data wiring DL and spaced apart from each other by a predetermined interval on the gate electrode 210, and a semiconductor pattern 220.

The gate wiring GL and the gate electrode 210 are formed of a first conductive pattern 210a formed of a titanium (Ti) conductive layer, which are sequentially formed on the substrate 200, and the second conductive pattern 210b is formed of a copper (Cu) conductive layer.

A gate insulating layer 215 is formed on the substrate 200, on which the gate electrode 210 is formed, and a semiconductor pattern 220 covering the gate electrode 210 is formed on the gate insulating layer 215.

The semiconductor pattern 220 may have a structure in which an active layer 220a, formed of an amorphous silicon material, and ohmic contact layers 220b, formed of an amorphous silicon material containing impurities, are sequentially stacked.

Source and drain electrodes 230a, 230b, which are spaced apart from each other so as to correspond to the gate electrode 210, are formed on the ohmic contact layers 220b, and a passivation layer 235 is formed on the source and drain electrodes 230a, 230b. The passivation layer 235 includes a contact hole H for exposing a part of the drain electrode 230b for connecting the drain electrode 230b and the pixel electrode 240.

Hereinafter, a method of forming the thin film transistor substrate according to the exemplary embodiment of the present invention including the aforementioned structure will be described.

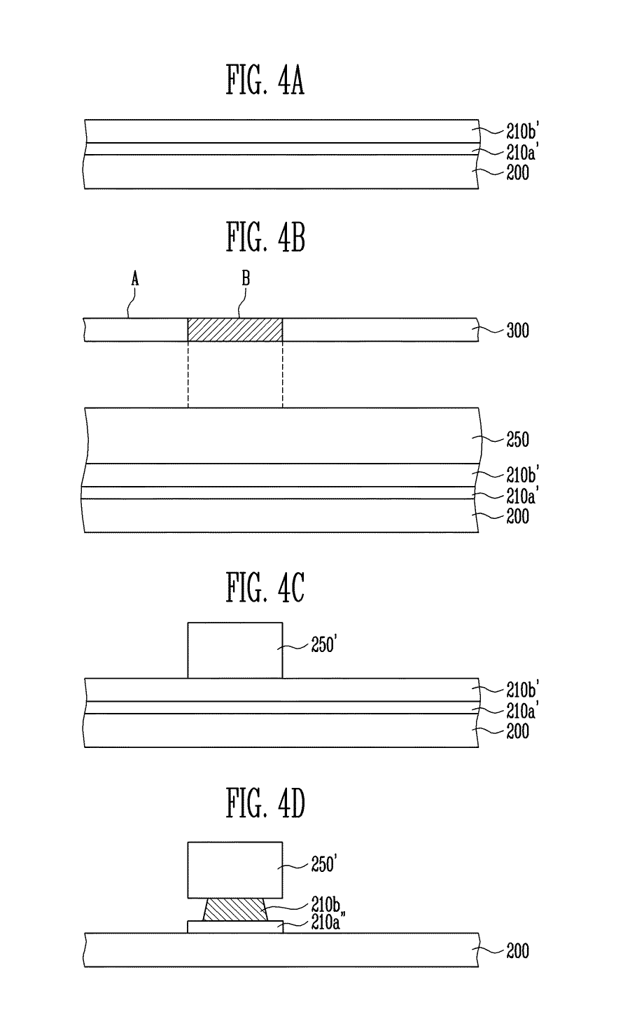

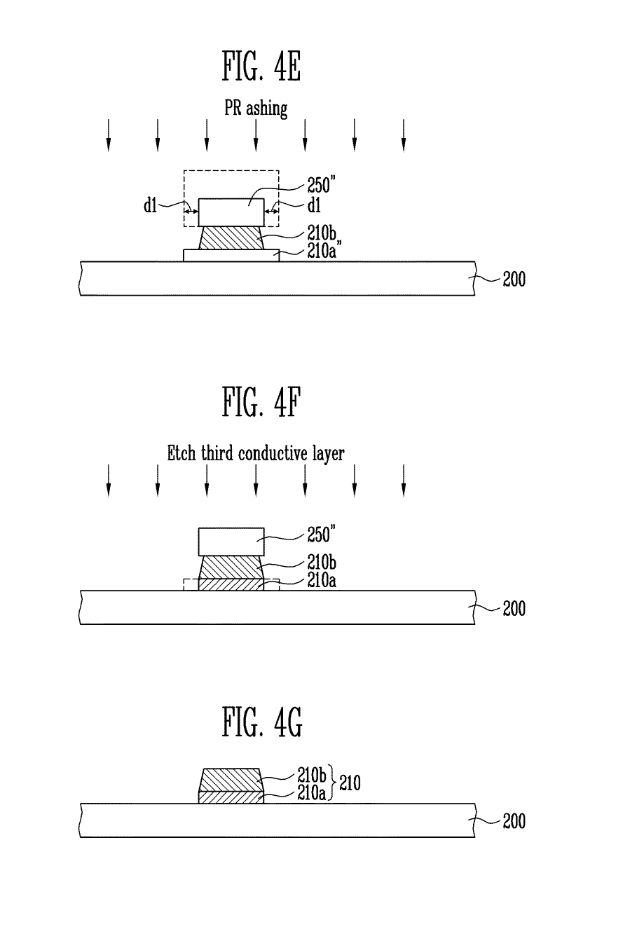

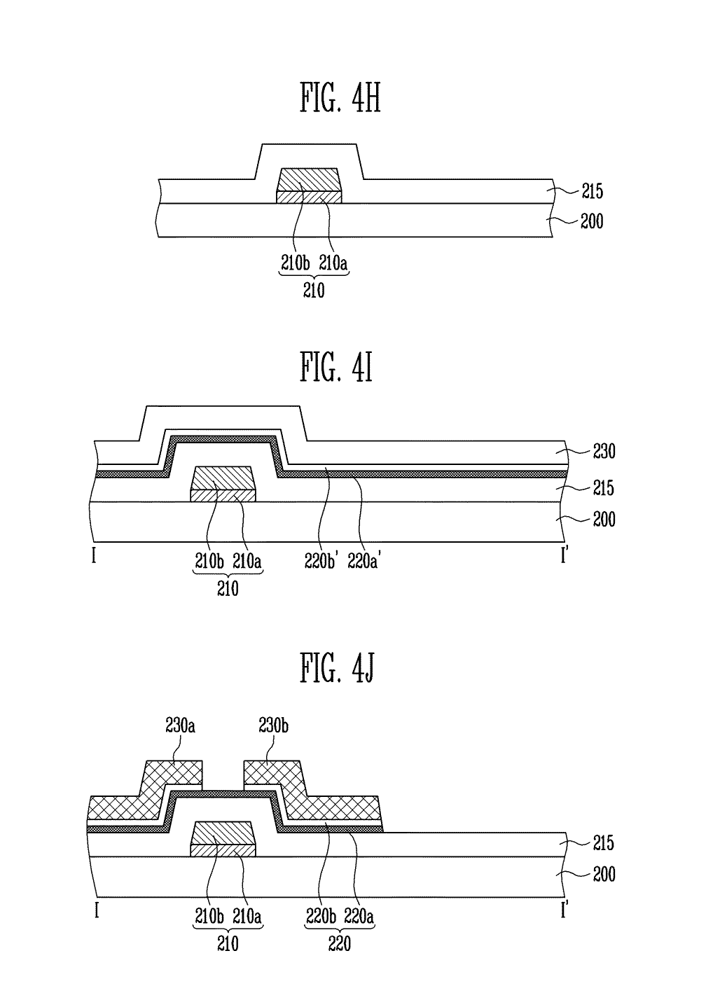

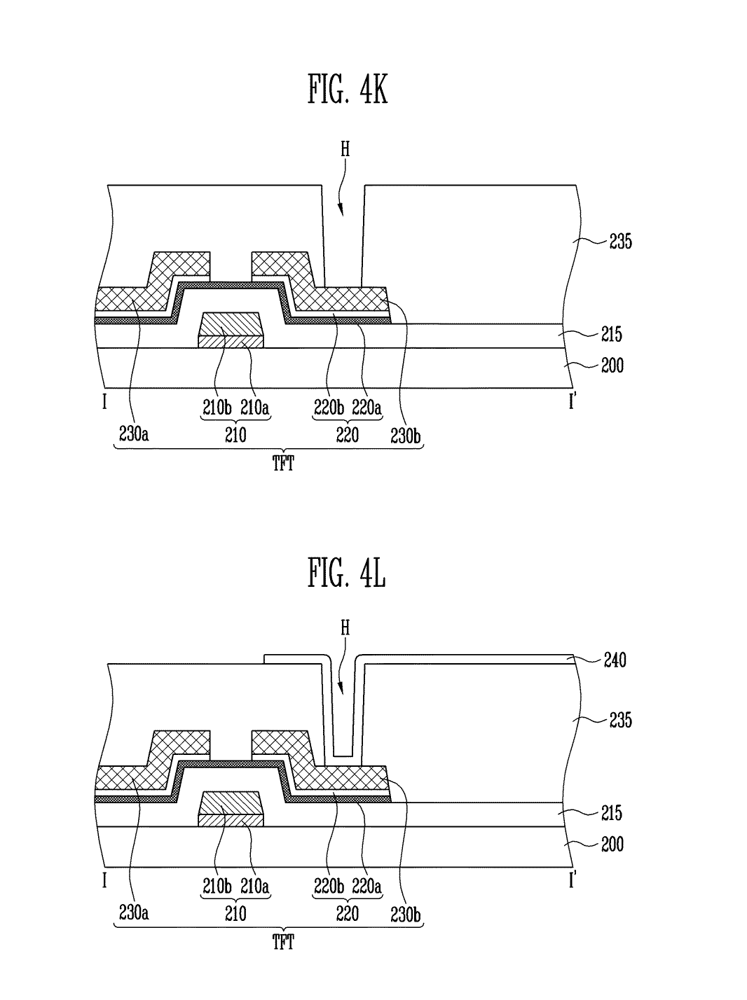

FIGS. 4A to 4L are cross-sectional views sequentially illustrating a process of fabricating the liquid crystal display device of FIG. 3.

Referring to FIG. 4A, a first conductive layer 210a′ and a second conductive layer 210b′ are sequentially formed on the substrate 200.

The second conductive layer 210b′ is formed of a copper conductive layer including copper (Cu) or a copper alloy, and has a thickness of about 2,000 to 8,000 Å.

The first conductive layer 210a′ may increase adhesion between the substrate 200 and the second conductive layer 210b′, and may be formed of a titanium (Ti) conductive layer serving as a barrier for preventing copper ions of the second conductive layer 210b′ from being diffused to the substrate 200, and having a thickness of about 0 to 500 Å.

Next, referring to FIG. 4B, a photoresist film 250 is formed on the substrate 200 on which the first and second conductive layers 210a′ and 210b′ are sequentially formed. An exposure mask 300 spaced apart from the photoresist layer 250 by a predetermined interval is disposed on the photoresist film 250, and then a first photoresist pattern 250′ illustrated in FIG. 4C is formed by performing a mask process including a series of unit processes, such as exposure, development, and etching. The exposure mask 250 includes a transmissive unit A for allowing light to pass through, and a blocking unit B for blocking light.

Subsequently, referring to FIG. 4D, a second conductive pattern 210b and a third conductive layer 210a″ are formed by performing a wet etching process on the first and second conductive layers 210a′ and 210b′ formed on the substrate 200 by using the first photoresist pattern 250′ as an etching mask. The first and second conductive layers 210a′ and 210b′ are etched in a batch manner.

In this case, oxon (2KHSO₅.KHSO₄.K₂SO₄) for etching the copper (Cu) conductive layer that is the second conductive layer 210b′, and a mixed liquid in which oxon and ammonium fluoride (NH₄F) are mixed for etching the titanium (Ti) conductive layer that is the first conductive layer 210a′ may be used as an etchant used in the wet etching process.

Referring to FIG. 4E, a second photoresist pattern 250″ is formed so that both lateral surfaces of the third conductive layer 210a″ are exposed to the outside by ashing processing the first photoresist pattern 250′. A spaced distance dl between the first and second photoresist patterns 250′ and 250″ may be 0.2 to 0.3 μm.

Referring to FIG. 4F, a first conductive pattern 210a having a pattern structure corresponding to the second photoresist pattern 250″ is formed by etching processing the third conductive layer 210″ exposed to the outside by using the second photoresist pattern 250″ as an etching mask.

In the etching operation, a dry etching method is used, and gas including any one of SF₆ and CF₄ with helium (He) as a base may be selected. Particularly, the helium (He) gas may have a flow rate about 50 to 150 sccm (standard cubic centimeter per minute) within a vacuum chamber, and SF₆ may also have a flow rate about 50 to 150 sccm. In this case, a pressure within the vacuum chamber may be set to be 10 to 50 mtorr, a source of the RF power may be set to have 500 to 2,000 W, and a bias power level may be set to 0 to 1,000 W.

Referring to FIG. 4G, the first and second conductive patterns 210a and 210b sequentially formed on the substrate 200 are formed by removing the second photoresist pattern 250″. The first and second conductive patterns 210a and 210b configure the gate electrode 210 of the thin film transistor TFT (see FIG. 3).

Next, referring to FIG. 4H, a gate insulation layer 215 is formed on an entire surface of the substrate 200 on which the gate electrode 210 is formed. The gate insulating layer 215 may include an inorganic insulating material formed by a single layer including one selected from a silicon oxide (SiO₂) layer, a silicon nitride (SiN) layer, and a silicon oxinitride (SiON), or a stacked layer including two or more layers selected from a silicon oxide (SiO₂) layer, a silicon nitride (SiN) layer, and a silicon oxinitride (SiON).

Next, referring to FIG. 4I, a first amorphous silicon material layer 220a′ and a second amorphous silicon material layer 220b′, which is doped with a high concentration of impurities, are sequentially formed on the substrate 200 on which the gate insulating layer 215 is formed. Further, a conductive material layer 230 is formed on the second amorphous silicon material layer 220b′.

The conductive material layer 230 may be formed in a single layer including one selected from the group consisting of molybdenum (Mo), tungsten (W), aluminum neodymium (AlNd), titanium (Ti), aluminum (Al), silver (Ag), and an alloy thereof or a mixture thereof, or in a dual layer or multilayer structure including molybdenum (Mo), aluminum (Al), or silver (Ag), which is a low resistance material, in order to decrease wiring resistance. That is, in order to decrease wiring resistance, the conductive material layer 230 may be formed by sequentially stacking the multilayer conductive layer, and particularly, the conductive material layer 230 may have a multilayer structure including Mo/Al/Mo, MoW/AlNd/MoW, Mo/Ag/Mo, Mo/Ag alloy/Mo, or Ti/Al/Mo.

Next, referring to FIG. 4J, the source electrode 230a and the drain electrode 230b, which overlap the gate electrode 210 and are spaced apart from each other by a predetermined interval on the gate insulating layer 210, are formed through a mask process using a diffraction mask or a halfton mask.

Simultaneously, ohmic contact layers 220b positioned under the source electrode 230a and the drain electrode 230b and corresponding to the source electrode 230a and the drain electrode 230b, respectively, and an active layer 230a exposed to the outside in a space region between the source electrode 230a and the drain electrode 230b, are formed. In this case, the ohmic contact layers 220b and the active layer 220a configure the semiconductor pattern 220.

Referring to FIG. 4K, a passivation layer 235, including a contact hole H for exposing a part of the drain electrode 230 to the outside, is formed on the substrate 200 on which the source electrode 230a and the drain electrode 230b are formed.

The passivation layer 235 may be formed of any one insulating material selected from an inorganic insulating material and an organic insulating material.

An example of the inorganic insulating material may include an insulating oxide, such as silicon oxide (SiOx), silicon nitride (SiNx), tungsten oxide (WOx), aluminum oxide (AlxOx), molybdenum oxide (MoOx), titanium oxide (TiOx), zinc oxide (ZnOx), and tin oxide (SnOx).

An example of the organic insulating material may include a general commercial polymer (PMMA and PS), polymer derivatives having a phenol group, an acryl-based polymer, an imide-based polymer, an arylether-based polymer, an amide-based polymer, a fluorine-based polymer, and a vinyl alcohol-based polymer.

Next, referring to FIG. 4L, a pixel electrode 240 electrically connected to the drain electrode 230 is formed on the substrate 200 on which the passivation layer 235 is formed. The pixel electrode 240 may be formed of a transparent conductive material, for example, a transparent metal material, such as an indium-tin-oxide (ITO) or an indium-zinc-oxide (IZO).

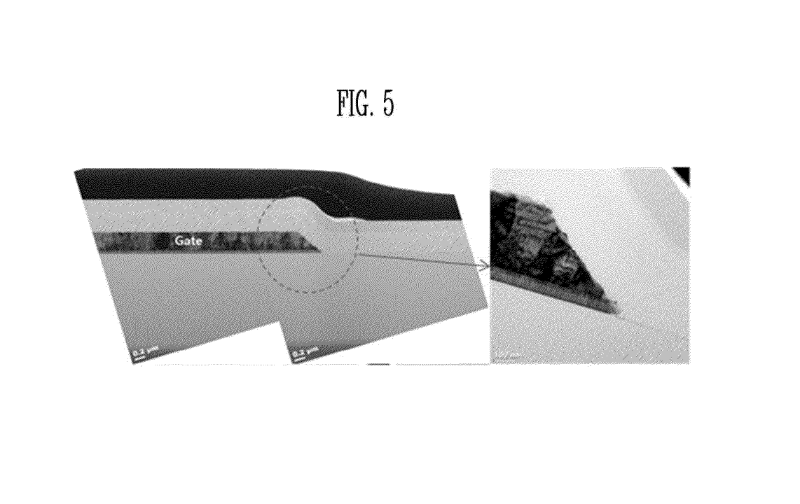

FIG. 5 is an SEM picture for the process of fabricating the metal wiring according to an exemplary embodiment of the present invention.

FIG. 5 is a picture showing a state where the titanium (Ti) conductive layer remaining on the lateral surface of the copper (Cu) conductive layer is removed through the wet etching process, the PR ashing process, and the dry etching process using helium (He) gas as a base in the gate wiring having the dual structure including the titanium (Ti)/copper (Cu) conductive layer.

Because the gate wiring uses the helium (He) gas as reaction gas in the dry etching process, it is possible to prevent the copper (Cu) conductive layer that is the topmost layer from being corroded, and improve reliability of the wiring by removing the titanium (Ti) conductive layer remaining on the lateral surface of the cooper (Cu) conductive layer.

In summary, copper (Cu) has poor adhesion for a lower structure, such as an insulating substrate including glass, and a semiconductor layer, and weak chemical-resistant characteristics for a chemical material, so that when copper (Cu) is exposed to a chemical material in a subsequent process, copper (Cu) is easily oxidized or corroded. Accordingly, although it is difficult to use the copper (Cu) single wiring, it is much easier to use the copper (Cu) wiring in the form of a dual layer including a barrier layer in a lower part thereof. Titanium (Ti), having excellent chemical-resistant characteristics, may be used as the barrier layer.

The metal wiring including the dual layers is etched by a batch-type collective etching process using the etchant. Titanium (Ti) has excellent chemical-resistant characteristics, so that titanium (Ti) is minimally etched by the etchant including no hydrofluoric acid in the batch-type etching process.

Accordingly, even though over etching is sufficiently processed in the wet etching process, selectivity between copper (Cu) and titanium (Ti) is large, and a significant residue of titanium (Ti) is left on the lateral surface of the copper (Cu), thereby causing a defect resulting in an increase in a leakage current and a greater likelihood of short circuits, thereby degrading reliability.

According to the method of fabricating the metal wiring according to the present invention, it is possible to remove the residue of titanium (Ti) left on the lateral surface of the copper (Cu) by dry etching the dual metal wiring including titanium (Ti)/copper (Cu) by using the helium (He) reaction gas, thereby improving reliability of the metal wiring.

Further, the dry etching process is performed using the helium (He) reaction gas, and not chlorine (Cl) reaction gas, thereby preventing copper (Cu) positioned in the topmost layer of the dual metal wiring from being corroded.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A method of fabricating metal wiring, comprising:
sequentially forming first and second conductive layers on a substrate;
forming a first photosensitive film pattern on the first and second conductive layers;
etching parts of the first and second conductive layers by using the first photosensitive film pattern as a mask to form first and second conductive patterns;
forming a second photosensitive film pattern positioned inside the first photosensitive film pattern by a predetermined interval by ashing the first photosensitive film pattern;
etching an exposed first conductive pattern by using the second photosensitive film pattern as a mask; and
removing the second photosensitive film pattern.

2. The method of claim 1, wherein the first conductive layer comprises titanium (Ti), and the second conductive layer comprises copper (Cu).

3. The method of claim 1, wherein the etching of the exposed first conductive pattern comprises plasma-processing the substrate, on which the second photosensitive film pattern is formed, within a vacuum chamber having a helium (He) gas atmosphere.

4. The method of claim 3, wherein the helium gas (He) atmosphere in the vacuum chamber comprises any one of SF₆ and CF₄, with helium (He) gas as a base.

5. The method of claim 4, wherein the helium (He) has a flow rate in a range of 50 to 150 sccm within the vacuum chamber.

6. The method of claim 1, wherein the first and second conductive patterns are formed by etching the first and second conductive layers using an etchant in a batch manner.

7. The method of claim 1, further comprising forming a capping layer on the second conductive pattern.

8. The method of claim 7, wherein the capping layer comprises copper (Cu).

9. A method of fabricating a thin film transistor substrate, comprising:
forming gate wiring extended in a first direction and a gate electrode connected to the gate wiring in a switching region on a substrate comprising a pixel region and the switching region arranged within the pixel region;
forming a gate insulating layer on the gate wiring and a gate electrode;
forming a semiconductor layer overlapping the gate electrode, data wiring extended in a second direction so as to cross the gate wiring, a source electrode connected to the data wiring, and a drain electrode spaced apart from the source electrode by a predetermined interval on the gate insulating layer;
forming a passivation layer comprising a contact hole for exposing a part of the drain electrode on the data wiring, the source electrode, and the drain electrode; and
forming a pixel electrode, which is in contact with the drain electrode through the contact hole, on the passivation layer,
wherein the forming of the gate wiring and the gate electrode comprises:
sequentially forming first and second conductive layers on the substrate;
forming a first photosensitive film pattern on the first and second conductive layers;
etching parts of the first and second conductive layers by using the first photosensitive film pattern as a mask to form first and second conductive patterns;
forming a second photosensitive film pattern positioned inside the first photosensitive film pattern by a predetermined interval by ashing the first photosensitive film pattern;
etching an exposed first conductive pattern by using the second photosensitive film pattern as a mask; and
removing the second photosensitive film pattern.

10. The method of claim 9, wherein the first conductive layer comprises titanium (Ti), and the second conductive layer comprises copper (Cu).

11. The method of claim 9, wherein the etching of the exposed first conductive pattern comprises plasma-processing the substrate, on which the second photosensitive film pattern is formed, within a vacuum chamber having a helium (He) gas atmosphere.

12. The method of claim 11, wherein the helium (He) gas atmosphere in the vacuum chamber comprises any one of SF₆ and CF₄, with helium (He) gas as a base.

13. The method of claim 12, wherein the helium (He) has a flow rate of 50 to 150 sccm within the vacuum chamber.

14. The method of claim 9, wherein the first and second conductive patterns are formed by etching the first and second conductive layers using an etchant in a batch manner.

15. The method of claim 9, further comprising forming a capping layer on the second conductive pattern.

16. The method of claim 9, wherein the capping layer comprises copper (Cu).
